(19) United States
(12) Patent Application Publication
(10) Pub. No.: US 2021/0189563 A1
(43) Pub. Date: Jun. 24, 2021

(54) FLOW HOMOGENIZING PLATE AND GAS HOMOGENIZING DEVICE FOR PROCESS CHAMBER

(71) Applicant: Beijing Juntai Innovation Technology Co., Ltd., Beijing (CN)

(72) Inventor: Shicheng YUAN, Beijing (CN)

(21) Appl. No.: 16/094,570

(22) PCT Filed: Jul. 13, 2018
(86) PCT No.: PCT/CN2018/095579

§ 371 Date: Oct. 18, 2018

(30) Foreign Application Priority Data
Jul. 14, 2017 (CN) 201710576540.8

(51) Int. Cl. C23C 16/455

(52) U.S. Cl. CPC C23C 16/45565; C23C 16/45574

(57) ABSTRACT

A gas homogenizing device for a process chamber includes a flow homogenizing plate, a first isolation plate and a second isolation plate. The flow homogenizing plate includes a first guide slot opened on the first surface, a second guide slot opened on a second surface opposite to the first surface; and at least one first outlet hole. The at least one first inlet end of the first guide slot is in communication with a first gas source, and the at least one second inlet end of the second inlet end is in communication with a second gas source. The at least one first outlet end of the first guide slot is in communication with the at least one second outlet end of the second guide slot through the at least one first outlet hole.

This application claims priority from Chinese patent application No. 201710576540.8 titled “GAS HOMOGENIZING DEVICE FOR LPCVD PROCESS CHAMBER” filed with the China National Intellectual Property Administration on Jul. 14, 2017, the disclosure of which is incorporated herein by reference in its entirety.

### TECHNICAL FIELD

The present disclosure relates to a manufacturing process technology of thin film cells, and particularly relates to a flow homogenizing plate and a gas homogenizing device for a process chamber.

### BACKGROUND

The key to the current development of the photovoltaic industry is to reduce the cost of solar cell production. Copper Indium Gallium Selenium (CIGS) thin film solar cells have properties such as low production cost, low pollution, no degradation, good low-light performance and high photoelectric conversion rate. Low Pressure Chemical Vapor Deposition (LPCVD) is used in the manufacturing process of CIGS thin film solar cells to produce thin films.

### SUMMARY

Some embodiments of the disclosure provide a gas homogenizing device for a process chamber, including:

a flow homogenizing plate, including:

a first surface and a second surface disposed oppositely; a first guide slot opened on the first surface, wherein the first guide slot has at least one first inlet end and at least one first outlet end, the at least one first inlet end being in communication with a first gas source; a second guide slot formed on the second surface, wherein the second guide slot has at least one second inlet end and at least one second outlet end, the at least one second inlet end being in communication with a second gas source; and at least one first outlet hole extending from the first surface through the second surface, the at least one first outlet end and the at least one second outlet end being in communication via the at least one first outlet hole;

a first isolation plate located on the first surface of the flow homogenizing plate and configured to block the first guide slot and an end of each of the at least one first outlet hole; and a second isolation plate located on the second surface of the flow homogenizing plate and configured to block the second guide slot, and the second isolation plate including at least one second outlet hole in communication with the at least one first outlet hole.

In some embodiments of the disclosure, the gas homogenizing device for a process chamber is a gas homogenizing device for an LPCVD process chamber.

In some embodiments of the disclosure, the flow homogenizing plate further includes a first inlet channel extending from a bottom surface of the first guide slot through the second surface, the second isolation plate further includes a first inlet hole in communication with the at least one first inlet end and the first inlet channel; and the second isolation plate further includes a second inlet hole in communication with the at least one second inlet end.

In some embodiments of the disclosure, the first guide slot and the second guide slot both have a branched structure, and the at least one first inlet end includes a plurality of first inlet ends, the at least one first outlet end includes a plurality of first outlet ends, the at least one second inlet end includes a plurality of second inlet ends, the at least one second outlet end includes a plurality of second outlet ends, the at least one first outlet hole includes a plurality of outlet holes, and the at least one second outlet hole includes a plurality of outlet holes.

In some embodiments of the disclosure, in the branched structure, each grade of the branched structure has a cross-sectional area smaller than an upper grade in the branched structure.

In some embodiments of the disclosure, each of the plurality of first outlet holes has the same aperture; and each of the plurality of second outlet holes has the same aperture.

In some embodiments of the disclosure, each of the plurality of first outlet holes has the same aperture as each of the plurality of second outlet holes.

In some embodiments of the disclosure, the flow homogenizing plate further includes a first recess opened on the first surface and a second recess opened on the second surface, wherein the first recess and the second recess are each provided with a seal ring.

In some embodiments of the disclosure, the process chamber further includes a cooling plate disposed on a surface of the second isolation plate away from the flow homogenizing plate, wherein the cooling plate includes: a second inlet channel configured to communicate with the first inlet hole; and a third inlet channel configured to communicate with the second inlet hole.

In some embodiments of the disclosure, the cooling plate further includes: a cooling groove, a cooling channel configured to introduce a coolant, and a plurality of third outlet holes in communication with the plurality of second outlet holes.

In some embodiments of the disclosure, the cooling channel is disposed in the cooling groove which is opened on a surface of the cooling plate adjacent to the second isolation plate.

In some embodiments of the disclosure, the cooling channel has a zigzag shape.

In some embodiments of the disclosure, the plurality of third outlet holes are stepped holes which have an aperture at an end adjacent to the second isolation plate larger than at an end of the plurality of third outlet holes away from the second isolation plate.

In some embodiments of the disclosure, an end of each of the plurality of third outlet holes adjacent to the second isolation plate is in communication with a corresponding second outlet hole of the plurality of second outlet holes, and an aperture of the end of each of the plurality of third outlet holes adjacent to the second isolation plate is larger than an aperture of each of the plurality of second outlet holes.

Some other embodiments of the disclosure provide a flow homogenizing plate, including:

a first surface and a second surface disposed oppositely; a first guide slot opened on the first surface, wherein the first guide slot has at least one first inlet end in communication with a first gas source and at least one first outlet end; a second guide slot opened on the second surface, wherein the second guide slot has at least one second inlet end and at least one second outlet end, the at least one second inlet end being in communication with a second gas source; and at least one first outlet hole extending from the first surface through the second surface, the at least one first outlet end and the at least one second outlet end being in communication via the at least one first outlet hole.

In some embodiments of the disclosure, the flow homogenizing plate further includes a first inlet channel extending from a bottom surface of the first guide slot through the second surface, the at least one first inlet end being in communication with the first inlet channel.

In some embodiments of the disclosure, the first guide slot and the second guide slot both have a branched structure, and the at least one first inlet end includes a plurality of first inlet ends, the at least one first outlet end includes a plurality of first outlet ends, the at least one second inlet end includes a plurality of second inlet ends, the at least one second outlet end includes a plurality of second outlet ends, and the at least one first outlet hole includes a plurality of outlet holes.

In some embodiments of the disclosure, the flow homogenizing plate further includes a first recess opened on the first surface and a second recess opened on the second surface, wherein the first recess and the second recess are each provided with a seal ring.

### BRIEF DESCRIPTION OF DRAWINGS

The drawings described herein are intended to provide a further understanding of the present disclosure, and are intended to be a part of the present disclosure. The exemplary embodiments of the present disclosure and the description thereof are for explaining the present disclosure and do not constitute an undue limitation of the present disclosure. In the drawing:

FIG. 1 is a schematic view showing an application of the gas homogenizing device for a process chamber provided in some embodiments of the disclosure;

FIG. 2 is a schematic view showing a configuration of the gas homogenizing device for a process chamber provided in some embodiments of the disclosure;

FIG. 3 is a structural schematic view showing a first isolation plate;

FIG. 4 is a structural schematic view showing a flow homogenizing plate;

FIG. 5 is a cutaway view along the direction A-A as shown in FIG. 4;

FIG. 6 is an enlarged view of FIG. 5 at C;

FIG. 7 is a cutaway view along the direction B-B as shown in FIG. 4;

FIG. 8 is an enlarged view of FIG. 7 at D,

FIG. 9 is an enlarged view of FIG. 7 at E;

FIG. 10 is a structural schematic view showing a second isolation plate;

FIG. 11 is a structural schematic view showing a cooling plate;

FIG. 12 is a cutaway view along the direction F-F as shown in FIG. 11;

FIG. 13 is an enlarged view of FIG. 12 at H;

FIG. 14 is a cutaway view along the direction G-G as shown in FIG. 11;

FIG. 15 is an enlarged view of FIG. 14 at I;

FIG. 16 is a cutaway view along the direction M-M as shown in FIG. 11;

FIG. 17 is a cross-section view of the gas homogenizing device for a process chamber;

FIG. 18 is an enlarged view of FIG. 17 at J;

FIG. 19 is another cross-section view of the gas homogenizing device for a process chamber; and

FIG. 20 is an enlarged view of FIG. 19 at K.

### DETAILED DESCRIPTION

The embodiments of the disclosure will now be described in detail with the examples thereof shown in the drawings throughout which, the same or similar reference signs refer to the same or similar elements or elements with the same or similar functions. The embodiments described below with reference to the drawings are merely illustrative, and are used only for the purpose of explaining the disclosure and should not be interpreted as limitations to the disclosure.

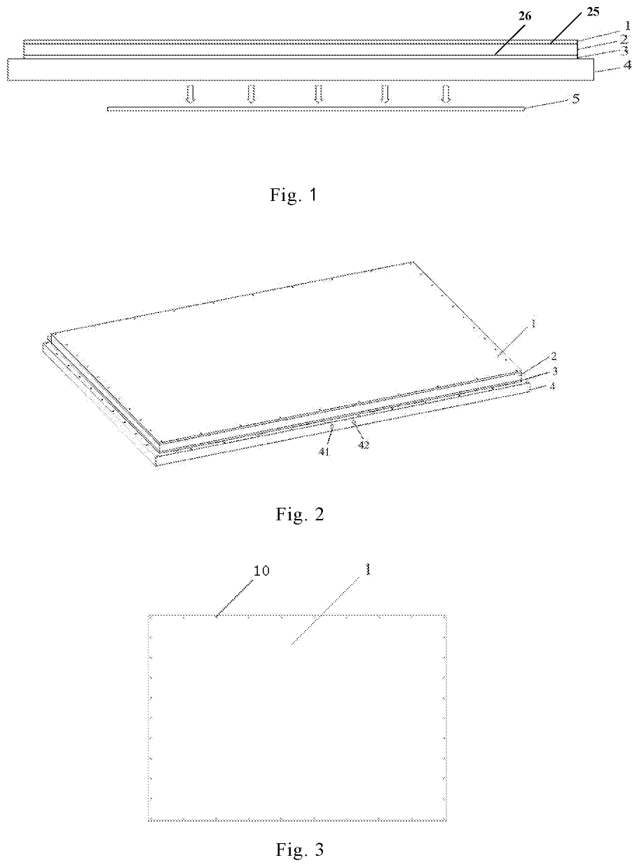

Referring to FIGS. 1 and 2, FIG. 1 is a schematic view showing an application of the gas homogenizing device for a process chamber provided in some embodiments of the disclosure, and FIG. 2 is a schematic view showing a configuration of the gas homogenizing device for a process chamber provided in some embodiments of the disclosure.

As shown in FIG. 1, some embodiments of the disclosure provide a gas homogenizing device for a process chamber, which includes a first isolation plate 1, a flow homogenizing plate 2 and a second isolation plate 3. The flow homogenizing plate 2 is provided with a first surface 25 and a second surface 26 disposed oppositely. The first isolation plate 1 is located on the first surface 25 of the flow homogenizing plate 2, and the second isolation plate 3 is located on the second surface 26 of the flow homogenizing plate 2.

In some embodiments of the disclosure, the gas homogenizing device for a process chamber further includes a cooling plate 4 disposed on a surface of the second isolation plate 3 away from the flow homogenizing plate 2. The cooling plate 4 is configured to keep a surface temperature of the gas homogenizing device at a relatively low range all the time.

In some embodiments of the disclosure, as shown in FIG. 2, the cooling plate 4 is provided with a second inlet channel 41 and a third inlet channel 42.

As shown in FIGS. 1 and 2, through the gas homogenizing device for a process chamber provided in the disclosure, a reactant gas is introduced into the process chamber and mixed in the flow homogenizing plate 2. The mixed gas is diffused onto a surface of a glass substrate 5.

In some embodiments of the disclosure, the reactant gas includes water vapor, hydrogen, borane, diethyl zinc, and the like.

In some embodiments of the disclosure, the gas homogenizing device for a process chamber is used in the production of copper indium gallium selenide (CIGS) thin film solar cells for depositing a uniform transparent conductive film on a surface of a large-sized glass substrate.

FIG. 3 is a structural schematic view showing a first isolation plate. In some embodiments of the disclosure, as shown in FIG. 3, the first isolation plate 1 has a plate shape. The first isolation plate 1 may be made of various materials as long as the first isolation plate 1 does not react with the reactant gas.

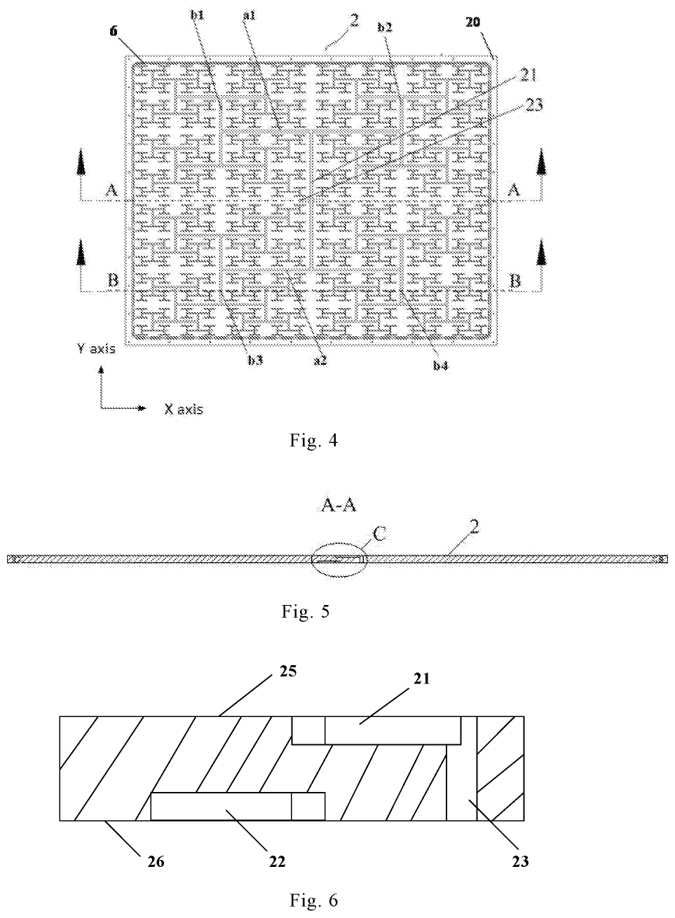

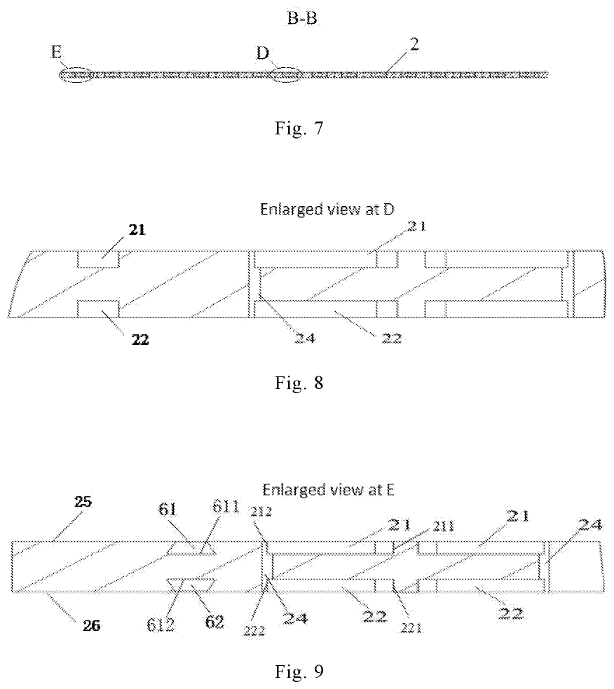

FIG. 4 is a structural schematic view showing a flow homogenizing plate, FIG. 5 is a cutaway view along the direction A-A as shown in FIG. 4, FIG. 6 is an enlarged view of FIG. 5 at C, FIG. 7 is a cutaway view along the direction B-B as shown in FIG. 4, FIG. 8 is an enlarged view of FIG. 7 at D, FIG. 9 is an enlarged view of FIG. 7 at E.

As shown in FIGS. 7 and 8, the flow homogenizing plate 2 includes a first guide slot 21 opened on the first surface 25, a second guide slot 22 opened on the second surface 26, and at least one first outlet hole 24 extending from the first surface 25 through the second surface 26. In that, the B-B direction is associated with a position of the first outlet hole 24; and D is a region where the first outlet hole 24 is located.

As shown in FIG. 9, the first guide slot 21 has at least one first inlet end 211 and at least one first outlet end 212, and the second guide slot 22 has at least one second inlet end 221 and at least one second outlet end 222. The at least one first inlet end 211 is in communication with a first gas source, and the at least one second inlet end 221 is in communication with a second gas source. The at least one first outlet end 212, the at least one second outlet end 222 and the at least one first outlet hole 24 are in communication.

In some embodiments of the disclosure, the first guide slot 21 and the second guide slot 22 have the same layout and size in the flow homogenizing plate.

In some embodiments of the disclosure, the at least one first inlet end 211 corresponds to the at least one second inlet end 221 one by one, and the at least one first outlet end 212, the at least one second outlet end 222 and the at least one first outlet hole 24 correspond to each other one by one. The first outlet end 212 is in communication with the respective second outlet end 222 via the first outlet hole 24.

The flow homogenizing plate 2 homogenizes a flow in such a way that a gas of the first gas source enters the flow homogenizing plate 2 through the first inlet end 211 of the first guide slot 21, and enters the first outlet hole 24 through the first outlet end 212. A gas of the second gas source enters the flow homogenizing plate 2 through the second inlet end 221 of the second guide slot 22, and enters the first outlet hole 24 through the second outlet end 222, thereby being mixed with the gas of the first gas source flowing out of the first outlet end 212.

In some embodiments of the disclosure, the first guide slot 21 and the second guide slot 22 both have a branched structure, and the at least one first inlet end 211 includes a plurality of first inlet ends 211, the at least one first outlet end 212 includes a plurality of first outlet ends 212, the at least one second inlet end 221 includes a plurality of second inlet ends 221, the at least one second outlet end 222 includes a plurality of second outlet ends 222, the at least one first outlet hole 24 includes a plurality of first outlet holes 24.

Referring to FIG. 4, in some embodiments of the disclosure, the first guide slot 21 has a branched structure. For example, the first guide slot 21, which is symmetrical about the X and Y axes, respectively, is processed in accordance with the law of one divided into two, two into four, four into eight, eight into sixteen . . . That is, as shown in FIG. 4, guide slots a1 and a2 are separated from the first guide slot 21, i.e., two guide slots are separated from one. Guide slots b1 and b2 are separated from the guide slot a1, and guide slots b3 and b4 are separated from the guide slot a2, i.e., four guide slots are separated from two, and so on. As shown in FIG. 4, the X axis is an axis extending along a length direction of the flow homogenizing plate 2 and passing through the center of the flow homogenizing plate 2, and the Y axis is an axis extending along a width direction of the flow homogenizing plate 2 and passing through the center of the flow homogenizing plate 2. The first guide slot 21 of the branched structure has a plurality of first inlet ends 211 and a plurality of first outlet ends 212.

In some embodiments of the disclosure, the second guide slot 22 has a branched structure, and the branched structure of the second guide slot has the same layout and size as the branched structure of the first guide slot 21, thus facilitating processing. The second guide slot 22 of the branched structure has a plurality of second inlet ends 221 and a plurality of second outlet ends 222.

In some embodiments of the disclosure, in the branched structure, each grade of the branched structure has a cross-sectional area in a plane perpendicular to an extending direction thereof smaller than an upper grade in the branched structure. In some embodiments, the first guide slot 21 and the second guide slot 22 are completely symmetrical except for a starting position (the starting position of the first guide slot is where the first inlet end begins introducing gas, while the starting position of the second guide slot is where the second inlet end begins introducing gas). Ends (an end of the first guide slot being the first outlet end, and an end of the second guide slot being the second outlet end) of all guide slots are uniformly distributed in both horizontal and vertical directions. Each of the guide slots is provided with a small hole at an end thereof so that the first guide slot is communication with the second guide slot. This small hole is the above described first outlet hole 24.

As shown in FIGS. 5 and 6, in some embodiments of the disclosure, the flow homogenizing plate 2 further includes a first inlet channel 23. The first inlet channel 23 extends from a bottom surface of the first guide slot 21 through the second surface 26. The bottom surface of the first guide slot 21 refers to a surface adjacent to the second surface 26. In that, the A-A direction in FIGS. 4 and 5 is associated with a position of the first inlet channel 23; and C in FIG. 5 is a region where the first inlet channel 23 is located.

In some embodiments of the disclosure, the plurality of first inlet ends 211 are in communication with the first gas source through the first inlet channel 23, and the plurality of second inlet end 221 are in communication with the second gas source.

FIG. 9 is an enlarged view of FIG. 7 at E. In some embodiments of the disclosure, the flow homogenizing plate 2 includes a first recess 61 opened on the first surface 25 and a second recess 62 opened on the second surface 26. The first recess 61 and the second recess 62 are provided with seal rings 611, 612, respectively. The seal ring 611 makes the flow homogenizing plate 2 in seal contact with the first isolation plate 1, and the seal ring 612 makes the flow homogenizing plate 2 in seal contact with the second isolation plate 3. In that, E in FIGS. 7 and 9 are regions where the first recess 61 and the second recess 62 are located. By means of the first recess 61 and the second recess 62 provided on the flow homogenizing plate, the first isolation plate 1 and the second isolation plate 3 seal the flow homogenizing plate more tightly, thus preventing gas from exiting the flow homogenizing plate 2.

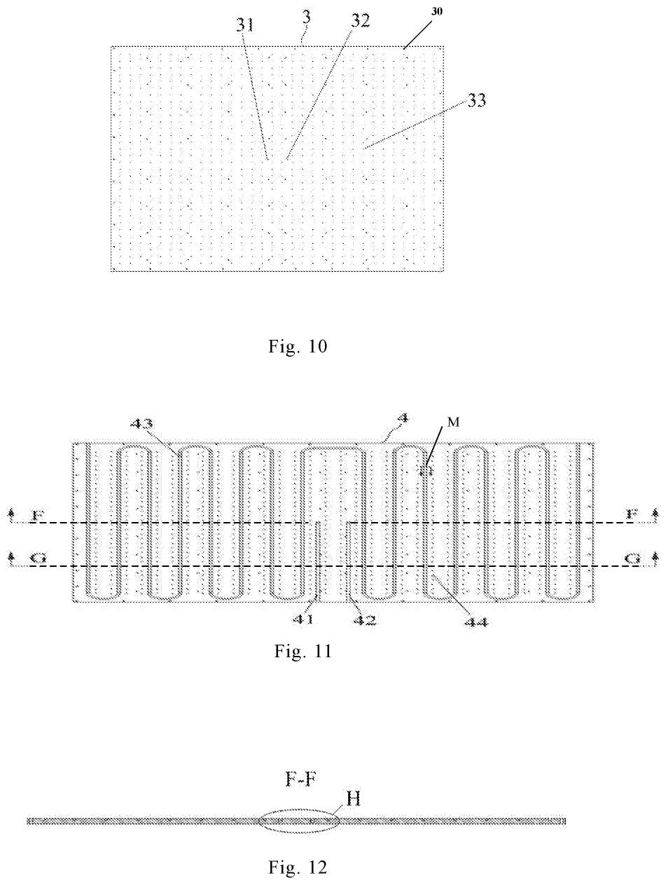

FIG. 10 is a structural schematic view showing a second isolation plate. As shown in FIG. 10, the second isolation plate 3 is provided with at least one second outlet hole 33 in communication with respective first outlet holes 24 on the flow homogenizing plate 2. Gases from the first and second gas sources are mixed at the flow homogenizing plate 2 before being discharged into the process chamber via the first outlet hole 24 and the second outlet hole 33, thus achieving an effect of homogenizing the gas.

In some embodiments of the disclosure, there are a plurality of first outlet holes 24 and a plurality of second outlet holes 33.

In some embodiments of the disclosure, each of the plurality of first outlet holes 24 has the same aperture, and each of the plurality of second outlet holes 33 has the same aperture, thereby improving uniformity of the gas discharged from the plurality of second outlet holes 33 and thus improving uniformity of the film layer.

In some embodiments of the disclosure, each of the plurality of first outlet holes 24 has the same aperture as each of the plurality of second outlet holes 33, thereby preventing turbulence of the gas.

In some embodiments of the disclosure, as shown in FIG. 10, the second isolation plate 3 is provided with a first inlet hole 31 and a second inlet hole 32.

In some embodiments of the disclosure, the first inlet end 211, the first inlet channel 23, the first inlet hole 31 and the first gas source are in communication. The second inlet end 221, the second inlet hole 32 and the second gas source are in communication. Thus, the gas of the first gas source passes through the first inlet hole 31 of the second isolation plate 3, the first inlet channel 23 and the first inlet end 211 of the first guide slot 21 in consequence before entering the flow homogenizing plate 2. The gas of the second gas source passes through the second inlet hole 32 of the second isolation plate 3, the second inlet end 221 of the second guide slot 22 in consequence before entering the flow homogenizing plate 2.

In some embodiments of the disclosure, the first isolation plate 1, the flow homogenizing plate 2 and the second isolation plate 3 are fixedly connected via a fastener. Referring to FIGS. 1, 4, and 10, the first isolation plate 1, the flow homogenizing plate 2 and the second isolation plate 3 are provided with holes 10, 20 and 30 for receiving the fastener, respectively.

In some embodiments of the disclosure, the first isolation plate 1 is configured to block the first guide slot 21 and an end of the at least one first outlet hole 24 on the first surface 25, thereby preventing the reactant gas from exiting at an end of the first guide slot 21 and the first outlet hole 24. The second isolation plate 3 is configured to block the second guide slot 22 and make the gas processed by the flow homogenizing plate 2 flow out through the first outlet hole 24.

In some embodiments of the disclosure, the first and second gas sources correspond to different reactant gases, respectively. The gas of the first gas source enters the first inlet channel 23 via the first inlet hole 31, and thus enters the first guide slot 21. The gas of the second gas source enters the second guide slot 22 via the second inlet hole 32. Since the first guide slot 21 is in communication with the second guide slot 22 via the first outlet hole 24, gases from the first and second gas sources get mixed at a surface of the second isolation plate 3 adjacent to the flow homogenizing plate 2, thereby obtaining the mixed gas. The mixed gas is diffused into the process chamber via the plurality of second outlet holes 33.

Since the plurality of second outlet holes 33 have the same aperture, a uniform diffusion of the gas is ensured, thereby improving shaping quality of the thin film in CIGS thin film cells.

In some embodiments of the disclosure, an inside of the process chamber is in a low vacuum and high temperature environment. The entered reactant gas will deposit a film layer on its surface when encountering a high temperature object. When reaching a certain thickness, the deposited film layer will block the outlet hole of the homogenizing device for a process chamber, and the film layer deposited on the second surface of the gas homogenizing device for a process chamber will fall off onto the glass substrate, eventually affecting the quality of the film layer deposited on the glass surface. Therefore, the gas homogenizing device for a process chamber provided in some embodiments of the disclosure further includes a cooling plate 4.

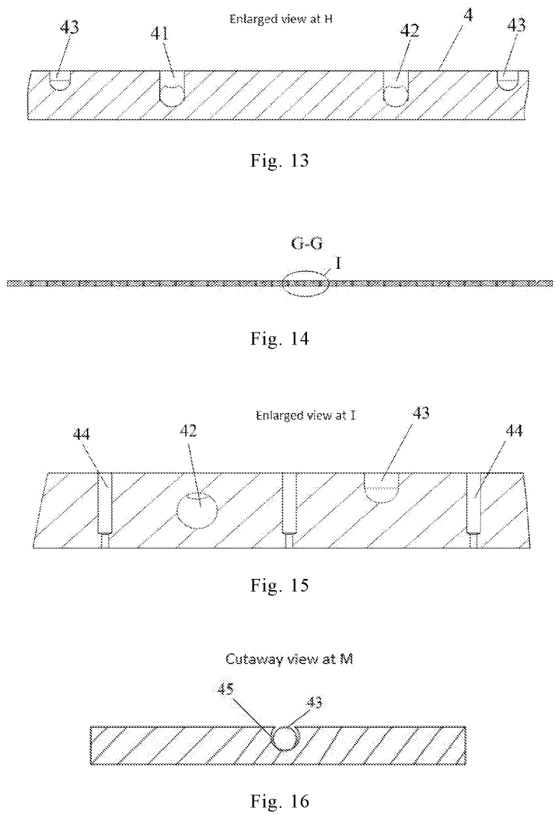

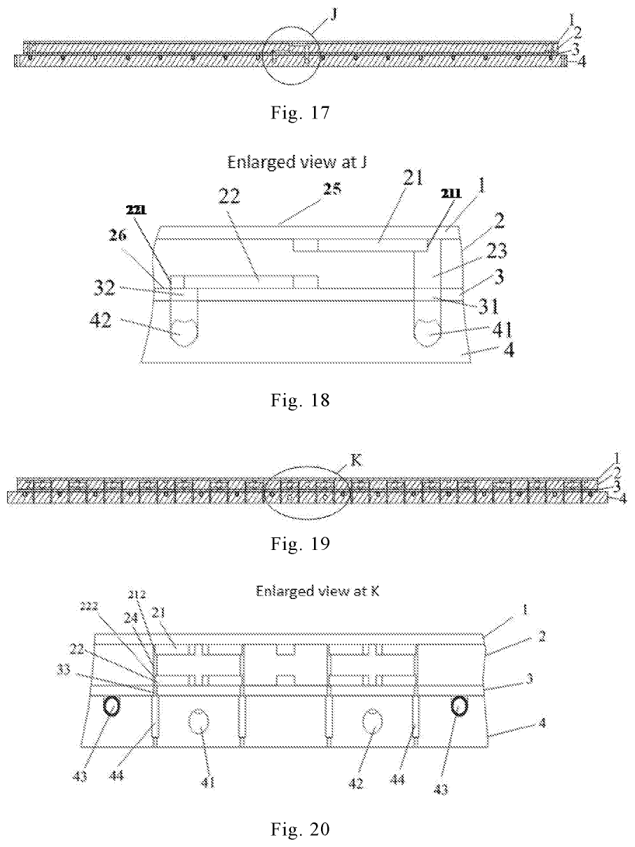

FIG. 11 is a structural schematic view showing a cooling plate, FIG. 12 is a cutaway view along the direction F-F as shown in FIG. 11, FIG. 13 is an enlarged view of FIG. 12 at H, FIG. 14 is a cutaway view along the direction G-G as shown in FIG. 11, and FIG. 15 is an enlarged view of FIG. 14 at I. FIG. 16 is a cutaway view along the direction M-M as shown in FIG. 11; FIG. 17 is a cross-section view of the gas homogenizing device for a process chamber; FIG. 18 is an enlarged view of FIG. 17 at J; FIG. 19 is another cross-section view of the gas homogenizing device for a process chamber; and FIG. 20 is an enlarged view of FIG. 19 at K.

In some embodiments of the disclosure, as shown in FIGS. 11-16, the cooling plate 4 is provided with a cooling groove 45, a cooling channel 43 and a plurality of third outlet holes 44. The plurality of third outlet holes 44 are in communication with the plurality of second outlet holes 33.

In some embodiments of the disclosure, as shown in FIG. 16, the cooling channel 43 is provided within the cooling groove 45 and supplied with a coolant.

In some embodiments of the disclosure, as shown in FIG. 11, the cooling plate 4 is provided with a second inlet channel 41 and a third inlet channel 42. As shown in FIG. 18, the second inlet channel 41 is in communication with the first inlet hole 31 on the second isolation plate 3 and the first gas source, respectively, and the third inlet channel 42 is in communication with the second inlet hole 32 on the second isolation plate 3 and the second gas source, respectively.

In that, the F-F direction in FIGS. 11 and 12 is associated with positions of the second inlet channel 41 and the third inlet channel 42. H in FIGS. 12 and 13 is a region where the second inlet channel 41 and the third inlet channel 42 are located. The G-G direction in FIGS. 11 and 14 is associated with positions of the third outlet hole 44, the second inlet channel 41, the third inlet channel 42 and the cooling channel 43. I in FIGS. 14 and 15 is a place containing the third inlet channel 42, the cooling channel 43 and the third outlet holes 44.

In some embodiments of the disclosure, the cooling channel 43 is disposed in the cooling groove 45 which is opened on a surface of the cooling plate 4 adjacent to the second isolation plate 3, so as to cool the gas passing through the cooling plate 4 and the gas passing through the second isolation plate 3 simultaneously.

In some embodiments of the disclosure, the cooling channel 43 has a zigzag shape to extend an effective cooling length of the cooling channel 43 as much as possible.

By providing the cooling plate, the gas passing through the cooling plate 4 and the gas passing through the second isolation plate 3 perform energy exchange with the coolant passing through the cooling channel 43 so that a surface temperature of the gas homogenizing device is kept in a relatively low range all the time. Without the high temperature conditions required by depositing the film layer, a surface growth rate of the film layer on the gas homogenizing device is reduced, thereby prolonging the maintenance time of the gas homogenizing device and thus improving the production efficiency.

As shown in FIGS. 17 and 18, the gas of the first gas source passes through the second inlet channel 41, the first inlet hole 31, and the first inlet channel 23 in sequence before entering the first guide slot 21. The gas of the second gas source enters the third inlet channel 42, the second inlet hole 32 before entering the second guide slot 22.

As shown in FIGS. 19 and 20, since the first guide slot 21 is in communication with the second guide slot 22 via the first outlet hole 24, gases from the first and second gas sources get mixed at a surface of the second isolation plate 3 adjacent to the flow homogenizing plate 2 to obtain the mixed gas. The mixed gas is diffused into the process chamber via the plurality of second outlet holes 33 and the plurality of third outlet holes 44.

In some embodiments of the disclosure, the gas homogenizing device for a process chamber includes: a first isolation plate 1, a flow homogenizing plate 2 and a second isolation plate 3.

The first inlet hole 31 on the second isolation plate 3, the first inlet channel 23 on the flow homogenizing plate 2 and the first inlet end 211 of the first guide slot 21 on the flow homogenizing plate 2 are in communication, and the first inlet hole 31 on the second isolation plate 3 is in communication with the first gas source.

The second inlet hole 32 on the second isolation plate 3 is in communication with the second inlet end 221 of the second guide slot 22 on the flow homogenizing plate 2, and the second inlet hole 32 on the second isolation plate 3 is in communication with the second gas source.

The plurality of first outlet ends 212 of the first guide slot 21 and the plurality of second outlet ends 222 of the second guide slot 22 are in communication with the second outlet hole 33 on the second isolation plate 3 via the plurality of first outlet holes 24 on the flow homogenizing plate 2.

Thus, by means of the gas homogenizing device for a process chamber provided in the embodiment of the disclosure, the gas of the first gas source passes through the first inlet hole 31 of the second isolation plate 3, the first inlet channel 23 and the first inlet end 211 of the first guide slot 21 in sequence before entering the first guide slot 21, thereby realizing a uniform flow of the gas of the first gas source in the flow homogenizing plate 2 via the first guide slot 21. The gas of the second gas source may pass through the second inlet hole 32 of the second isolation plate 3 and the second inlet end 221 of the second guide slot 22 in consequence before entering the second guide slot 22, thereby realizing a uniform flow of the gas of the second gas source in the flow homogenizing plate 2 via the second guide slot 22.

The homogenized gas of the first gas source enters the plurality of first outlet holes 24 of the flow homogenizing plate 2 via the plurality of first outlet ends 212 of the first guide slot 21. Meanwhile, the homogenized gas of the second gas source enters the plurality of first outlet holes 24 of the flow homogenizing plate 2 via the plurality of second outlet ends 222 of the second guide slot 22, and gets mixed with the gas of the first gas source outflowing the plurality of first outlet ends 212 of the first guide slot 21 to obtain the mixed gas. The mixed gas outflows through the plurality of second outlet holes 33 of the second isolation plate 3 to diffuse over the glass substrate, thereby ensuring uniformity of the gas diffused on the glass substrate and improving the quality of the finished film.

In some embodiments of the disclosure, the gas homogenizing device for a process chamber includes: a first isolation plate 1, a flow homogenizing plate 2, a second isolation plate 3 and a cooling plate 4. The second inlet channel 41 in the cooling plate 4, the first inlet hole 31 in the second isolation plate 3, the first inlet channel 23 in the flow homogenizing plate 2 and the first inlet end 211 of the first guide slot 21 in the flow homogenizing plate 2 are in communication, and the second inlet channel 41 in the cooling plate 4 is in communication with the first gas source.

The third inlet channel 42 in the cooling plate 4, the second inlet hole 32 in the second isolation plate 3, and the second inlet end 221 of the second guide slot 22 in the flow homogenizing plate 2 are in communication, and the third inlet channel 42 in the cooling plate 4 is in communication with the second gas source.

The plurality of first outlet ends 212 of the first guide slot 21 and the plurality of second outlet ends 222 of the second guide slot 22 are in communication with the second outlet hole 33 on the second isolation plate 3 via the plurality of first outlet holes 24 on the flow homogenizing plate 2. The second outlet hole 33 of the second isolation plate 3 is in communication with the third outlet hole 44 of the cooling plate 4.

A surface of the cooling plate 4 adjacent to the second isolation plate 3 is provided with a cooling channel 43 to cooling the gas in the cooling plate 4 and the gas in the second isolation plate 3 simultaneously.

As shown in FIG. 18, the gas of the first gas source passes through the second inlet channel 41 in the cooling plate 4, the first inlet hole 31 in the second isolation plate 3, the first inlet channel 23 and the first inlet end 211 of the first guide slot 21 in consequence before entering the first guide slot 21. The gas of the first gas source is get homogenized in the flow homogenizing plate 2 via the first guide slot 21. The gas of the second gas source passes through the third inlet channel 42 on the cooling plate 4, the second inlet hole 32 of the second isolation plate 3, the second inlet end 221 of the second guide slot 22 in consequence before entering the second guide slot 22. The gas of the second gas source is get homogenized in the flow homogenizing plate 2 via the second guide slot 22.

As shown in FIG. 20, the homogenized gas of the first gas source enters the plurality of first outlet holes 24 of the flow homogenizing plate 2 via the plurality of first outlet ends 212 of the first guide slot 21. Meanwhile, the homogenized gas of the second gas source enters the plurality of first outlet holes 24 of the flow homogenizing plate 2 via the plurality of second outlet ends 222 of the second guide slot 22, and gets mixed with the gas of the first gas source outflowing the plurality of first outlet ends 212 of the first guide slot 21 to obtain the mixed gas. The mixed gas outflows through the plurality of second outlet holes 33 of the second isolation plate 3 and the third outlet holes 44 of the cooling plate 4 in sequence to be diffused onto the glass substrate. The coolant in the cooling channel 43 cools the gas in the second outlet hole 33 of the second isolation plate 3 and the gas in the third outlet hole 44 of the cooling plate 4 to avoid depositing a layer on the surface of the gas homogenizing device for a process chamber when the gas at the gas homogenizing device for a process chamber encounters a high temperature object, so as to prevent the film layer from affecting the uniformity of the gas flowing to the substrate in the process chamber, thereby improving the quality of the finished film.

In some embodiments of the disclosure, the third outlet hole 44 is a stepped hole. The plurality of third outlet holes 44 have an aperture at an end adjacent to the second isolation plate 3 larger than at an end of the third outlet hole 44 away from the second isolation plate 3.

In some embodiments of the disclosure, there are a plurality of third outlet holes 44. An end of each of the plurality of third outlet holes 44 adjacent to the second isolation plate 3 is in communication with the corresponding second outlet hole 33 of the plurality of second outlet holes 33.

In some embodiments of the disclosure, the plurality of third outlet holes 44 have an aperture at an end adjacent to the second isolation plate 3 larger than an aperture of the second outlet hole 33, so as to ensure a more smooth flow of gas. In some embodiments of the disclosure, the plurality of third outlet holes 44 have the same aperture at an end away from the second isolation plate 3 and have an aperture equal to the aperture of each of the plurality of second outlet holes 33.

The structure, features, and effects of the present disclosure have been described in detail with reference to the embodiments shown in the drawings. The above embodiments are merely preferred embodiments of the present disclosure, and the scope of the disclosure is not limited as shown in the drawings. Any change made based on the idea of the present disclosure, or equivalent embodiments that are modified to equivalent variations, should still fall within the protection scope of the disclosure if they do not go beyond the spirit covered by the description and the drawings.

1. A gas homogenizing device for a process chamber, comprising:
a flow homogenizing plate, including:
a first surface and a second surface disposed oppositely;
a first guide slot opened on the first surface, wherein the first guide slot has at least one first inlet end and at least one first outlet end, the at least one first inlet end being configured to be in communication with a first gas source;
a second guide slot opened on the second surface, wherein the second guide slot has at least one second inlet end and at least one second outlet end, the at least one second inlet end being configured to be in communication with a second gas source; and
at least one first outlet hole extending from the first surface through the second surface, the at least one first outlet end and the at least one second outlet end being in communication via the at least one first outlet hole;
a first isolation plate located on the first surface of the flow homogenizing plate and configured to block the first guide slot and an end of the at least one first outlet hole on the first surface; and
a second isolation plate located on the second surface of the flow homogenizing plate and configured to block the second guide slot, and the second isolation plate including at least one second outlet hole in communication with the at least one first outlet hole.

2. The gas homogenizing device for a process chamber according to claim 1, wherein, the gas homogenizing device for a process chamber is a gas homogenizing device for an LPCVD process chamber.

3. The gas homogenizing device for a process chamber according to claim 1, wherein the flow homogenizing plate further comprises a first inlet channel extending from a bottom surface of the first guide slot through the second surface;
the second isolation plate further includes a first inlet hole in communication with the at least one first inlet end and the first inlet channel;
the second isolation plate further includes a second inlet hole in communication with the at least one second inlet end.

4. The gas homogenizing device for a process chamber according to claim 2, wherein the first guide slot and the second guide slot both have a branched structure, and the at least one first inlet end includes a plurality of first inlet ends, the at least one first outlet end includes a plurality of first outlet ends, the at least one second inlet end includes a plurality of second inlet ends, the at least one second outlet end includes a plurality of second outlet ends, the at least one first outlet hole includes a plurality of first outlet holes, and the at least one second outlet hole includes a plurality of second outlet holes.

5. The gas homogenizing device for a process chamber according to claim 4, wherein in the branched structure, each grade of the branched structure has a cross-sectional area smaller than an upper grade in the branched structure.

6. The gas homogenizing device for a process chamber according to claim 4, wherein each of the plurality of first outlet holes has the same aperture, and each of the plurality of second outlet holes has the same aperture.

7. The gas homogenizing device for a process chamber according to claim 4, wherein each of the plurality of first outlet holes has the same aperture as each of the plurality of second outlet holes.

8. The gas homogenizing device for a process chamber according to claim 3, wherein the flow homogenizing plate further includes a first recess opened on the first surface and a second recess opened on the second surface;
wherein the first recess and the second recess are each provided with a seal ring.

9. The gas homogenizing device for a process chamber according to claim 3, further comprising a cooling plate disposed on a surface of the second isolation plate away from the flow homogenizing plate, wherein the cooling plate includes:
a second inlet channel configured to communicate with the first inlet hole; and
a third inlet channel configured to communicate with the second inlet hole.

10. The gas homogenizing device for a process chamber according to claim 9, wherein the cooling plate further comprises:
a cooling groove;
a cooling channel configured to introduce a coolant; and
a plurality of third outlet holes in communication with the plurality of second outlet holes.

11. The gas homogenizing device for a process chamber according to claim 10, wherein the cooling channel is disposed in the cooling groove which is opened on a surface of the cooling plate adjacent to the second isolation plate.

12. The gas homogenizing device for a process chamber according to claim 10, wherein the cooling channel has a zigzag shape.

13. The gas homogenizing device for a process chamber according to claim 10, wherein the plurality of third outlet holes are stepped holes, wherein an aperture at an end of the third outlet hole adjacent to the second isolation plate is larger than an aperture at an end of the third outlet holes away from the second isolation plate.

14. The gas homogenizing device for a process chamber according to claim 10, wherein an end of each of the plurality of third outlet holes adjacent to the second isolation plate is in communication with a corresponding second outlet hole of the plurality of second outlet holes, and an aperture of the end of each of the plurality of third outlet holes adjacent to the second isolation plate is larger than an aperture of each of the plurality of second outlet holes.

15. The gas homogenizing device for a process chamber according to claim 10, wherein the plurality of third outlet holes have the same aperture at an end away from the second isolation plate and have an aperture equal to the aperture of each of the plurality of second outlet holes.

16. A flow homogenizing plate, comprising:
a first surface and a second surface disposed oppositely;
a first guide slot opened on the first surface, wherein the first guide slot has at least one first inlet end and at least one first outlet end, the at least one first inlet end being configured to be in communication with a first gas source;
a second guide slot opened on the second surface, wherein the second guide slot has at least one second inlet end and at least one second outlet end, the at least one second inlet end being configured to be in communication with a second gas source; and
at least one first outlet hole extending from the first surface through the second surface, the at least one first outlet end and the at least one second outlet end being in communication via the at least one first outlet hole.

17. The flow homogenizing plate according to claim 16, wherein the flow homogenizing plate further includes a first inlet channel extending from a bottom surface of the first guide slot through the second surface, the at least one first inlet end being in communication with the first inlet channel.

18. The flow homogenizing plate according to claim 16, wherein the first guide slot and the second guide slot both have a branched structure, and the at least one first inlet end includes a plurality of first inlet ends, the at least one first outlet end includes a plurality of first outlet ends, the at least one second inlet end includes a plurality of second inlet ends, the at least one second outlet end includes a plurality of second outlet ends, the at least one first outlet hole includes a plurality of first outlet holes.

19. The flow homogenizing plate according to claim 16, wherein the flow homogenizing plate further includes a first recess opened on the first surface and a second recess opened on the second surface;
wherein the first recess and the second recess are each provided with a seal ring.
